(19) United States
(12) Patent Application Publication
(10) Pub. No.: US 2010/0326507 A1
(43) Pub. Date: Dec. 30, 2010

(54) SOLAR CELL AND MANUFACTURING METHOD THEREOF

(75) Inventors: Mitsuhiro Matsumoto, Gifu-shi (JP); Kazuya Murata, Anpachi-gun (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/825,529

(22) Filed: Jun. 29, 2010

(30) Foreign Application Priority Data
Jun. 30, 2009 (JP) 2009-155501

(51) Int. Cl. H01L 31/105; H01L 31/18

(52) U.S. Cl. 136/255; 438/87; 257/E31.061

(57) ABSTRACT

In a manufacturing method of a thin film solar cell in which a p-type layer, an i-type layer, and an n-type layer are layered, the i-type layer is an amorphous silicon layer, the n-type layer is a microcrystalline silicon layer, and in a process of forming the n-type layer, a doping concentration of an n-type dopant is increased as a distance from the i-type layer is increased.

### CROSS-REFERENCE TO RELATED APPLICATION

The entire disclosure of Japanese Patent Application No. 2009-155501 filed on Jun. 30, 2009, including specification, claims, drawings, and abstract, is incorporated herein by reference in its entirety.

### BACKGROUND

1. Technical Field

The present invention relates to a solar cell and a manufacturing method of a solar cell.

2. Related Art

Solar cells are known in which polycrystalline silicon, microcrystalline silicon, or amorphous silicon is used. In particular, a solar cell in which microcrystalline or amorphous silicon thin films are layered has attracted much attention in view of resource consumption, reduction of cost, and improvement in efficiency.

In general, a thin film solar cell is formed by sequentially layering a first electrode, one or more semiconductor thin film photovoltaic cells, and a second electrode over a substrate having an insulating surface. Each solar cell unit is formed by layering a p-type layer, an i-type layer, and an n-type layer from a side of incidence of light.

As a method of improving the conversion efficiency of the thin film solar cell, a method is known in which two or more types of photovoltaic cells are layered in the direction of light incidence. A first solar cell unit having a photovoltaic layer with a wider band gap is placed on the side of light incidence of the thin film solar cell, and then, a second solar cell unit having a photovoltaic layer with a narrower band gap than the first solar cell unit is placed. With this configuration, photovoltaic is enabled for a wide wavelength range of the incident light, and the conversion efficiency of the overall device can be improved.

For example, a structure is known in which an amorphous silicon (a-Si) solar cell unit is set as a top cell and a microcrystalline silicon (μc-Si) solar cell unit is set as a bottom cell. In particular, a technique is known in which an n-type layer in the amorphous silicon solar cell unit is formed in a two-layer structure of an amorphous silicon layer and a microcrystalline silicon layer.

In order to improve the conversion efficiency of the thin film solar cell, it is necessary to optimize the characteristics of the thin films of the solar cell, and improve an open voltage Voc, a short-circuit current density Jsc, and a fill factor FF.

### SUMMARY

According to one aspect of the present invention, there is provided a method of manufacturing a photovoltaic unit, comprising a first step in which a p-type thin film doped with a p-type dopant is formed, a second step in which an i-type amorphous silicon thin film is layered and formed over the p-type thin film, and a third step in which an n-type microcrystalline silicon thin film doped with an n-type dopant is layered and formed over the i-type amorphous silicon thin film, wherein, in the third step, a doping concentration of the n-type dopant of the n-type microcrystalline silicon thin film is increased as a distance from the i-type amorphous silicon thin film is increased.

According to another aspect of the present invention, there is provided a photovoltaic unit comprising a p-type thin film doped with a p-type dopant, an i-type amorphous silicon thin film layered over the p-type thin film, and an n-type microcrystalline silicon thin film layered over the i-type amorphous silicon thin film and doped with an n-type dopant, wherein, in the n-type microcrystalline silicon thin film, a doping concentration of the n-type dopant is increased as a distance from the i-type amorphous silicon thin film is increased.

### BRIEF DESCRIPTION OF THE DRAWINGS

A preferred embodiment of the present invention will be described in further detail based on the following drawings, wherein:

FIG. 1 is a drawing showing a structure of a tandem-type solar cell in a preferred embodiment of the present invention; and

FIG. 2 is a drawing showing a structure of an a-Si unit of the tandem-type solar cell in the preferred embodiment of the present invention.

### DETAILED DESCRIPTION

### Basic Structure

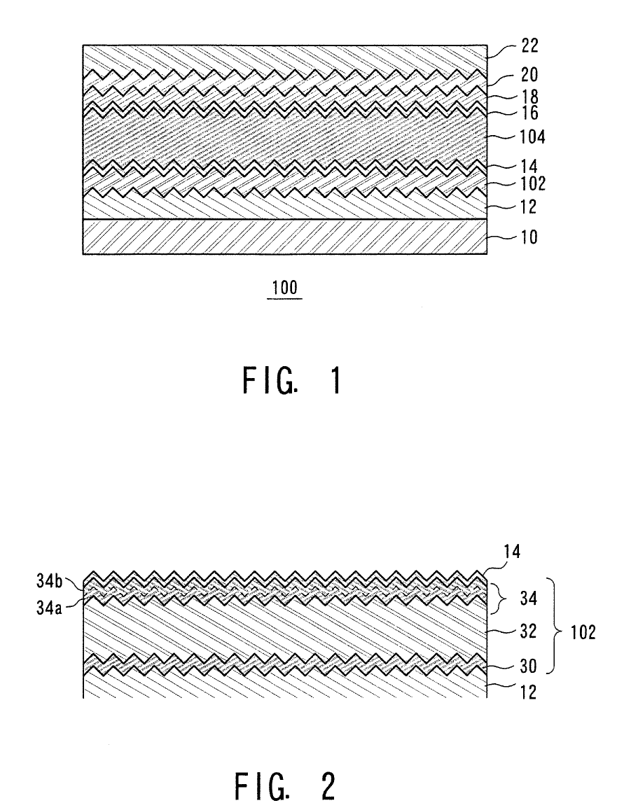

FIG. 1 is a cross sectional drawing showing a structure of a tandem-type solar cell 100 in a preferred embodiment of the present invention. The tandem-type solar cell 100 in the present embodiment has a structure in which a transparent insulating substrate 10 is set at a light incidence side, and a transparent conductive film 12, an amorphous silicon (a-Si) (photovoltaic) unit 102 functioning as a top cell and having a wide band gap, an intermediate layer 14, a microcrystalline silicon (μc-Si) (photovoltaic) unit 104 functioning as a bottom cell and having a narrower band gap than the a-Si unit 102, a first backside electrode layer 16, a second backside electrode layer 18, a filler 20, and a protective film 22 are layered from the light incidence side.

A structure and a method of manufacturing the tandem-type solar cell 100 in the preferred embodiment of the present invention will now be described. As the tandem-type solar cell 100 in the present embodiment is characterized by an n-type layer included in the a-Si unit 102, the n-type layer in the a-Si unit 102 will be particularly described in detail.

As the transparent insulating substrate 10, a material having light transmittance at least in a visible light wavelength region such as, for example, a glass substrate, a plastic substrate, or the like, may be used. The transparent conductive film 12 is formed over the transparent insulating substrate 10. For the transparent conductive film 12, it is preferable to use at least one of or a combination of a plurality of transparent conductive oxides (TCO) in which tin (Sn), antimony (Sb), fluorine (F), aluminum (Al), or the like is doped into tin oxide (SnO₂), zinc oxide (ZnO), indium tin oxide (ITO), or the like. In particular, zinc oxide (ZnO) is preferable because it has a high light transmittance, a low resistivity, and a high plasma endurance characteristic. The transparent conductive film 12 can be formed, for example, through sputtering. A thickness of the transparent conductive film 12 is preferably set in a range of greater than or equal to 0.5 μm and less than or equal to 5 μm. In addition, it is preferable to provide unevenness having a light confinement effect on a surface of the transparent conductive film 12.

Silicon-based thin films, that is, a p-type layer 30, an i-type layer 32, and an n-type layer 34, are sequentially layered over the transparent conductive film 12, to form the a-Si unit 102. FIG. 2 shows an enlarged cross sectional view of the portion of the a-Si unit 102.

The a-Si unit 102 may be formed through plasma CVD in which mixture gas of silicon-containing gas such as silane (SiH₄), disilane (Si₂H₆), and dichlorsilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) is made into plasma and a film is formed.

For the plasma CVD, for example, RF plasma CVD of 13.56 MHz is preferably applied. The RF plasma CVD may be of a parallel plate-type. Alternatively, a configuration may be employed in which a gas shower hole for supplying the mixture gas of the material is provided on a side of the parallel plate-type electrodes on which the transparent insulating substrate 10 is not placed. An input power density of the plasma is preferably greater than or equal to 5 mW/cm² and less than or equal to 100 mW/cm².

In general, the p-type layer 30, the i-type layer 32, and the n-type layer 34 are formed in different film formation chambers. The film formation chamber can be vacuumed using a vacuum pump, and an electrode for the RF plasma CVD is built into the film formation chamber. In addition, a transporting device of the transparent insulating substrate 10, a power supply and a matching device for the RF plasma CVD, pipes for supplying gas, etc. are provided.

The p-type layer 30 is formed over the transparent conductive film 12. The p-type layer 30 is set as a single layer of an amorphous silicon layer, a microcrystalline silicon layer, or a microcrystalline silicon carbide layer, or a combined layer in which a plurality of these layers are combined.

For example, the p-type layer 30 includes an amorphous silicon carbide layer in which an absorption coefficient with respect to light of a particular wavelength changes as the thickness is increased from the transparent conductive film 12 toward the i-type layer 32. In addition, in order to adjust the band gap and avoid influence of plasma during formation of the i-type layer 32, a buffer layer made of amorphous silicon carbide or microcrystalline silicon carbide may be formed over the low-absorption amorphous silicon carbide layer. More specifically, for example, a high-absorption amorphous silicon carbide layer doped with a p-type dopant (such as boron) in a first doping concentration is formed over the transparent conductive film 12, and a low-absorption amorphous silicon carbide layer doped with the p-type dopant (such as boron) in a second doping concentration which is lower than the first doping concentration is formed over the high-absorption amorphous silicon carbide layer. In this case, the second doping concentration is preferably set in a range of 1/5 to 1/10 of the first doping concentration.

Moreover, for example, the p-type layer 30 has a layered structure of an amorphous silicon carbide layer doped with a p-type dopant (such as boron), a silicon layer formed without being doped with the p-type dopant, and a buffer layer formed without being doped with the p-type dopant.

The p-type layer 30 can be formed by adjusting the mixture ratios of the silicon-containing gas, carbon-containing gas, p-type dopant-containing gas, and dilution gas, pressure, and plasma generating high-frequency power in the plasma CVD.

For the i-type layer 32, a non-doped amorphous silicon film formed over the p-type layer 30 and having a thickness of greater than or equal to 50 nm and less than or equal to 500 nm is employed. A film characteristic of the i-type layer 32 can be changed by adjusting the mixture ratios of silicon-containing gas and dilution gas, pressure, and plasma generating high-frequency power. In addition, the i-type layer 32 acts as a power generation layer of the a-Si unit 102.

For the n-type layer 34, an n-type microcrystalline silicon layer (n-type μc-Si:H) formed over the i-type layer 32, doped with an n-type dopant (such as phosphorus), and having a thickness of greater than or equal to 10 nm and less than or equal to 100 nm is employed. The film characteristic of the n-type layer 34 can be changed by adjusting the mixture ratios of the silicon-containing gas, carbon-containing gas, n-type dopant-containing gas, and dilution gas, pressure, and plasma generating high-frequency power.

In the present embodiment, the n-type layer 34 is formed such that the doping concentration of the n-type dopant is increased as the distance from the i-type layer 32 is increased. The doping concentration may be stepwise increased or continuously increased.

When the doping concentration is to be stepwise increased, first, a microcrystalline silicon layer 34a doped with an n-type dopant (such as phosphorus) in a first doping concentration or not doped with the n-type dopant is formed over the i-type layer 32. Then, a microcrystalline silicon layer 34b doped with the n-type dopant (such as phosphorus) in a second doping concentration which is higher than that of the microcrystalline silicon layer 34a may be formed over the microcrystalline silicon layer 34a.

In this case, in plasma CVD, while the plasma continues to be generated, the mixture ratios of the silicon-containing gas, carbon-containing gas, n-type dopant-containing gas, and dilution gas, pressure, and plasma generating high-frequency power may be adjusted, to consecutively form the microcrystalline silicon layer 34a and the microcrystalline silicon layer 34b. When the film formation condition is consecutively changed while the plasma is being generated, an interface layer 34c is formed between the microcrystalline silicon layer 34a and the microcrystalline silicon layer 34b. The interface layer 34c is formed in a very thin thickness.

More specifically, for example, the microcrystalline silicon layer 34a is formed in a state where a flow rate of phosphine (PH₃) which is the n-type dopant-containing gas (amount of supply (flow rate) of n-type dopant-containing gas) with respect to a flow rate of silane (SiH₄) which is the silicon-containing gas is set lower than 0.005, and then, the microcrystalline silicon layer 34b is formed with the flow rate of phosphine (PH₃), which is the n-type dopant-containing gas (amount of supply (flow rate) of n-type dopant-containing gas), with respect to the flow rate of silane (SiH₄) which is the silicon-containing gas, being changed to a value greater than or equal to 0.005.

When the doping concentration of the n-type layer 34 is to be continuously changed, the mixture ratios of the silicon-containing gas, carbon-containing gas, n-type dopant-containing gas, and dilution gas, pressure, and plasma generating high-frequency power are adjusted while the plasma is generated in the plasma CVD such that the doping concentration of the microcrystalline silicon layer on a side near the i-type layer 32 is lower than the doping concentration of the microcrystalline silicon layer on a side near the intermediate layer 14.

More specifically, the amount of supply (flow rate) of the n-type dopant-containing gas may be gradually increased. For example, film formation may be started in a state where the flow rate of phosphine (PH₃) which is the n-type dopant-containing gas (amount of supply (flow rate) of n-type dopant-containing gas) with respect to the flow rate of silane (SiH₄) which is the silicon-containing gas is set lower than 0.005, and then, the film formation is continued while the flow rate of phosphine (PH₃), which is the n-type dopant-containing gas (amount of supply (flow rate) of n-type dopant-containing gas), with respect to silane (SiH₄) which is the silicon-containing gas, is changed to a value greater than or equal to 0.005.

By employing the microcrystalline silicon layer as the n-type layer 34, lower absorption of the light and improvement in the contact characteristic with the intermediate layer 14 can be achieved, but as the flow rate of the doping gas (phosphine) with respect to the material gas (silane) during formation of the microcrystalline silicon layer is increased, the microcrystallization percentage is reduced. Therefore, as in the present embodiment, the microcrystalline silicon layer 34a having a low doping concentration or a non-doped concentration may be formed as a base layer, and the microcrystalline silicon layer 34b may be formed in a higher doping concentration over the microcrystalline silicon layer 34a, such that the crystallization percentage of the base layer may be improved and the overall doping concentration of the n-type layer 34 may be increased. As the base of the microcrystal layer, it is preferable to employ a layer which is formed with the flow rate of phosphine (PH₃) being less than or equal to 0.1% with respect to the flow rate of silane (SiH₄).

In addition, by consecutively forming the microcrystalline layer 34a and the microcrystalline silicon layer 34b while the plasma continues to be generated, it is possible to prevent formation of a plasma generated initial layer at the interface between the microcrystalline silicon layer 34a and the microcrystalline silicon layer 34b, and consequently, reduce defects at the interface between the microcrystalline silicon layer 34a and the microcrystalline silicon layer 34b.

The intermediate layer 14 is formed over the a-Si unit 102. For the intermediate layer 14, it is preferable to use the transparent conductive oxide (TCO) such as zinc oxide (ZnO) and silicon oxide (SiOx). In particular, it is preferable to use zinc oxide (ZnO) or silicon oxide (SiOx) doped with magnesium Mg. The intermediate layer 14 may be formed, for example, through sputtering. A thickness of the intermediate layer 14 is preferably in a range of greater than or equal to 10 nm and less than or equal to 200 nm. Alternatively, it is also possible to not provide the intermediate layer 14.

The μc-Si unit 104 in which a p-type layer, an i-type layer, and an n-type layer are sequentially layered is formed over the intermediate layer 14. The μc-Si unit 104 may be formed through plasma CVD in which mixture gas of silicon-containing gas such as silane (SiH₄), disilane (Si₂H₆), dichlorsilane (SiH₂Cl₂), carbon-containing gas such as methane (CH₄), p-type dopant-containing gas such as diborane (B₂H₆), n-type dopant-containing gas such as phosphine (PH₃), and dilution gas such as hydrogen (H₂) is made into plasma, and a film is formed.

Similar to the a-Si unit 102, for the plasma CVD, for example, RF plasma CVD of 13.56 MHz is preferably applied. The RF plasma CVD may be of the parallel plate-type. Alternatively, a configuration may be employed in which a gas shower hole for supplying the mixture gas of the material is provided on a side of the parallel plate-type electrode on which the transparent insulating substrate 10 is not placed. The input power density of the plasma is preferably set to greater than or equal to 5 mW/cm² and less than or equal to 100 mW/cm².

For example, the μc-Si unit 104 is formed by layering a p-type microcrystalline silicon layer (p-type μc-Si:H) having a thickness of greater than or equal to 5 nm and less than or equal to 50 nm and doped with boron, a non-doped i-type microcrystalline silicon layer (i-type μc-Si:H) having a thickness of greater than or equal to 0.5 μm and less than or equal to 5 μm, and an n-type microcrystalline silicon layer (n-type μc-Si:H) having a thickness of greater than or equal to 5 nm and less than or equal to 50 nm and doped with phosphorus.

The unit is not limited to the μc-Si unit 104, and any unit may be used so long as the i-type microcrystalline silicon layer (i-type μc-Si:H) is used as a power generation layer.

A layered structure of a reflective metal and a transparent conductive oxide (TCO) is formed over the μc-Si unit 104 as the first backside electrode layer 16 and the second backside electrode layer 18. As the first backside electrode layer 16, a transparent conductive oxide (TCO) such as tin oxide (SnO₂), zinc oxide (ZnO), and indium tin oxide (ITO) is used. As the second backside electrode layer 18, a metal such as silver (Ag) and aluminum (Al) can be used. The TCO may be formed, for example, through sputtering. The first backside electrode layer 16 and the second backside electrode layer 18 are preferably formed to a total thickness of approximately 1 μm. In addition, it is preferable to form unevenness on the surface of at least one of the first backside electrode layer 16 and the second backside electrode layer 18, to improve the light confinement effect.

The surface of the second backside electrode layer 18 is covered with the protective film 22 by the filler 20. The filler 20 and the protective film 22 may be formed of a resin material such as EVA and polyimide. With such a configuration, it is possible to prevent intrusion of moisture or the like into the power generation layer of the tandem-type solar cell 100.

Alternatively, a YAG laser (with a basic wave of 1064 nm and second harmonics of 532 nm) may be used to separate and pattern the transparent conductive film 12, the a-Si unit 102, the intermediate layer 14, the μc-Si unit 104, the first backside electrode layer 16, and the second backside electrode layer 18, to achieve a structure in which a plurality of cells are connected in series.

The basic structure of the tandem-type solar cell 100 in the preferred embodiment of the present invention has been described. The structure of the p-type layer 30 in the preferred embodiment will now be described.

### Examples

An example and a comparative example of a tandem-type solar cell 100 to which the p-type layer 30 of the above-described preferred embodiment is applied will now be described.

### Example

As the transparent insulating substrate 10, a glass substrate having a size of 33 cm×43 cm and a thickness of 4 mm was used. Over the transparent insulating substrate 10, a layer of SnO₂ having a thickness of 600 nm and having uneven shapes on the surface was formed through thermal CVD as the transparent conductive film 12. Then, the transparent conductive film 12 was patterned by a YAG laser in a strip shape. As the YAG laser, a YAG laser having a wavelength of 1064 nm, an energy density of 13 J/cm³, and a pulse frequency of 3 kHz was used.

The p-type layer 30, the i-type layer 32, and the n-type layer were sequentially formed over the transparent insulating substrate 10. TABLE 1 shows film formation conditions of the p-type layer 30 and the i-type layer 32, and TABLE 2 shows film formation conditions of the n-type layer 34. As the n-type layer 34, the microcrystalline silicon layer 34a was formed with the flow rate ratio of silane (SiH₄):hydrogen (H₂):phosphine (PH₃) being 1:100:0, and the microcrystalline silicon layer 34b was then formed with the flow rate ratio of silane (SiH₄):hydrogen (H₂):phosphine (PH₃) being 1:100:0.01, to realize a structure of Example 1. Here, the overall pressure of the material gas was 80 Pa, and the input power density to the plasma was 15 mW/cm².

In addition, as the n-type layer 34, one layer of microcrystalline silicon layer was formed with the flow rate ratio of silane (SiH₄):hydrogen (H₂):phosphine (PH₃) being 1:100:0.01, to realize a structure of Comparative Example 1.

TABLE 1

| | SUBSTRATE | GAS | | | |
|---|---|---|---|---|---|
| | TEMPER- | FLOW | REACTION | RF | THICK- |
| | ATURE | RATE | PRESSURE | POWER | NESS |
| LAYER | (° C.) | (sccm) | (Pa) | (W) | (nm) |
| p-TYPE | 180 | SiH₄: 20-40 | 80 | 30 | 25-50 |
| LAYER | | CH₄: 0-80 | | | |
| | | B₂H₆: 0-0.12 | | | |
| | | H₂: 400-2000 | | | |
| i-TYPE | 200 | SiH₄: 300 | 80 | 30 | 250 |
| LAYER | | H₂: 2000 | | | |

TABLE 2

| | | SUBSTRATE | GAS | | | |
|---|---|---|---|---|---|---|
| | | TEMPERA- | FLOW | REACTION | | THICK- |
| | | TURE | RATE | PRESSURE | RF POWER | NESS |
| | | (° C.) | (sccn) | (Pa) | (mW/cm2) | (nm) |
| EXAMPLE 1 | NON-DOPED | 180 | SiH₄: 20 | 80 | 15 | 15 |
| | MICROCRYSTALLINE | | H₂: 2000 | | | |
| | SILICON LAYER 34a | | PH₃: 0 | | | |
| | HIGHLY-DOPED | 180 | SiH₄: 20 | 80 | 15 | 15 |
| | MICROCRYSTALLINE | | H₂: 2000 | | | |
| | SILICON LAYER 34b | | PH₃: 0.2 | | | |
| COMPARA- | SINGLE LAYER | 180 | SiH₄: 20 | 80 | 15 | 30 |
| TIVE | | | H₂: 2000 | | | |
| XAMPLE 1 | | | PH₃: 0.2 | | | |

TABLE 3 shows film formation conditions of the μc-Si unit 104. The film formation conditions of the μc-Si unit 104 are not limited to these conditions, however.

TABLE 3

| | SUBSTRATE | GAS FLOW | REACTION | | |
|---|---|---|---|---|---|
| | TEMPERATURE | RATE | PRESSURE | RF POWER | |
| LAYER | (° C.) | (sccm) | (Pa) | (w) | THICKNESS |
| p-TYPE | 180 | SiH₄: 10 | 106 | 10 | 10 |
| LAYER | | H₂: 2000 | | | |
| | | B₂H₆: 0.03 | | | |
| i-TYPE | 200 | SiH₄: 100 | 133 | 20 | 2000 |
| LAYER | | H₂: 2000 | | | |
| n-TYPE | 200 | SiH₄: 10 | 133 | 20 | 20 |
| LAYER | | H₂: 2000 | | | |
| | | PH₃: 0.05 | | | |

Then, the YAG laser was radiated on a position aside from the patterning position of the transparent conductive film 12 by 50 μm, to pattern the a-Si unit 102 and the μc-Si unit 104 in a strip shape. As the YAG laser, a YAG laser having an energy density of 0.7 J/cm³ and a pulse frequency of 3 kHz was used.

An Ag electrode was then formed as the first backside electrode layer 16 through sputtering and a ZnO film was formed as the second backside electrode layer 18 through sputtering. YAG laser was radiated at a position aside from the patterning position of the a-Si unit 102 and the μc-Si unit 104 by 50 μm, to pattern the first backside electrode layer 16 and the second backside electrode layer 18 in a strip shape. As the YAG laser, a YAG laser having an energy density of 0.7 J/cm³ and a pulse frequency of 4 kHz was used.

TABLE 4 shows the open voltage Voc, short-circuit current density Jsc, fill factor FF, and efficiency η of each of the tandem-type solar cells 100 of Example 1 and Comparative Example 1. In TABLE 4, the values of Example 1 are shown as ratios, with the open voltage Voc, short-circuit current density Jsc, fill factor FF, and efficiency η of Comparative Example 1 being regarded as 1.

TABLE 4

| | | SHORT- | | |
|---|---|---|---|---|
| | | CIRCUIT | | |
| | OPEN | CURRENT | | |
| | VOLTAGE | DENSITY | | EFFICIENCY |
| | (Voc) | (Jsc) | F. F. | (η) |
| EXAMPLE 1 | 1.00 | 1.01 | 1.02 | 1.03 |
| COMPARATIVE | 1 | 1 | 1 | 1 |
| EXAMPLE 1 | | | | |

By employing a two-layer structure of the non-doped microcrystalline silicon layer 34a and a highly-doped microcrystalline silicon layer 34b as the n-type layer 34 as in Example 1, it was possible to improve the short-circuit current density Jsc and the fill factor FF compared to the case where a single layer structure of the highly-doped microcrystalline silicon layer is employed as in Comparative Example 1.

This can be deduced to be because the crystallization percentage of the non-doped microcrystalline silicon layer 34a which forms the base layer is high compared to the case where the highly-doped microcrystalline silicon layer is formed as a single layer, and the highly-doped microcrystalline silicon layer 34b was formed while maintaining the high crystallinity. It can be further deduced that, with this configuration, compared to the case where the highly-doped microcrystalline silicon layer is formed with a single layer as in Comparative Example 1, the resistivity in the thickness direction of the n-type layer 34 can be reduced, and consequently, the short-circuit current density Jsc and the fill factor FF are improved.

What is claimed is:

1. A method of manufacturing a photovoltaic unit, comprising:
a first step in which a p-type thin film doped with a p-type dopant is formed;
a second step in which an i-type amorphous silicon thin film is layered and formed over the p-type thin film; and
a third step in which an n-type microcrystalline silicon thin film doped with an n-type dopant is layered and formed over the i-type amorphous silicon thin film, wherein
in the third step, a doping concentration of the n-type dopant of the n-type microcrystalline silicon thin film is increased as a distance from the i-type amorphous silicon thin film is increased.

2. The method of manufacturing photovoltaic unit according to claim 1, wherein
in the third step, the doping concentration of the n-type dopant of the n-type microcrystalline silicon thin film is stepwise increased as the distance from the i-type amorphous silicon thin film is increased.

3. The method of manufacturing photovoltaic unit according to claim 1, wherein
in the third step, the doping concentration of the n-type dopant of the n-type microcrystalline silicon thin film is continuously increased as the distance from the i-type amorphous silicon thin film is increased.

4. The method of manufacturing photovoltaic unit according to claim 1, wherein
in the third step, silane is used as a material of the microcrystalline silicon, phosphine is used as a material of the n-type dopant, and, after the layering is started with a flow rate of phosphine being less than or equal to 0.1% of a flow rate of silane, the doping concentration of the n-type dopant is increased as the distance from the i-type amorphous silicon thin film is increased.

5. A photovoltaic unit comprising:
a p-type thin film doped with a p-type dopant;
an i-type amorphous silicon thin film layered over the p-type thin film; and
an n-type microcrystalline silicon thin film layered over the i-type amorphous silicon thin film and doped with an n-type dopant, wherein
in the n-type microcrystalline silicon thin film, a doping concentration of the n-type dopant is increased as a distance from the i-type amorphous silicon thin film is increased.

6. The photovoltaic unit according to claim 5, wherein
in the n-type microcrystalline silicon thin film, the doping concentration of the n-type dopant is stepwise increased as the distance from the i-type amorphous silicon thin film is increased.

7. The photovoltaic unit according to claim 5, wherein
in the n-type microcrystalline silicon thin film, the doping concentration of the n-type dopant is continuously increased as the distance from the i-type amorphous silicon thin film is increased.
